(19) United States
(12) Patent Application Publication
(10) Pub. No.: US 2026/0318990 A1
(43) Pub. Date: Oct. 15, 2026

(54) SCAN TEST ARCHITECTURE WITH A VARIABLE COMPRESSION RATIO

(71) Applicant: Microchip Technology Incorporated, Chandler, AZ (US)

(72) Inventors: Kenneth W. Ferguson, Burnaby (CA); Steven Yu Peng Ng, Vancouver (CA)

(73) Assignee: Microchip Technology Incorporated, Chandler, AZ (US)

(21) Appl. No.: 19/250,941

(22) Filed: Jun. 26, 2025

Related U.S. Application Data
(60) Provisional application No. 63/806,319, filed on May 15, 2025.
(60) Provisional application No. 63/787,468, filed on Apr. 11, 2025.

(51) Int. Cl. G01R 31/3185

(52) U.S. Cl. CPC G01R 31/318536; G01R 31/318547; G01R 31/318572

(57) ABSTRACT

A system comprising a scan chain comprising a plurality of scan channels coupled to combinational logic, wherein a scan channel comprises a plurality of memory elements arranged in series, wherein an input to the scan channel is to be serially shifted through the plurality of memory elements of the scan channel; and circuitry to, based on a value of a control signal couple inputs of a first subset of the plurality of scan channels to a scan input signal, the scan input signal to communicate a test pattern; and couple inputs of a second subset of the plurality of scan channels to outputs of other scan channels of the plurality of scan channels.

### CROSS-REFERENCE TO RELATED APPLICATIONS

This application claims the benefit of U.S. Provisional Patent Application No. 63/787,468, filed Apr. 11, 2025, and U.S. Provisional Patent Application No. 63/806,319, filed May 15, 2025.

### TECHNICAL FIELD

The present disclosure relates generally to logic testing, and more specifically to a scan test architecture with a variable compression ratio.

### BACKGROUND

Scan testing is used to test digital integrated circuits to efficiently identify defects. Scan testing involves the addition of scan cells (e.g., including flip-flops) to an integrated circuit design to enable internal signals to be accessed and controlled through a serial scan chain. Various test patterns are shifted into the scan chain, the combinational logic of the chip is executed (e.g., for a clock cycle), and the resulting outputs are loaded into the scan chain, shifted out, and analyzed (e.g., compared against an expected output) to identify defects and verify proper operation.

### SUMMARY OF THE INVENTION

Aspects provide a scan test architecture with a variable compression ratio.

An aspect provides a system comprising a scan chain comprising a plurality of scan channels coupled to combinational logic, wherein a scan channel comprises a plurality of memory elements arranged in series, wherein an input to the scan channel is to be serially shifted through the plurality of memory elements of the scan channel; and circuitry to, based on a value of a control signal couple inputs of a first subset of the plurality of scan channels to a scan input signal, the scan input signal to communicate a test pattern; and couple inputs of a second subset of the plurality of scan channels to outputs of other scan channels of the plurality of scan channels.

Another aspect provides an apparatus comprising a scan chain comprising a plurality of scan channels coupled to combinational logic, wherein a scan channel comprises a plurality of memory elements arranged in series, wherein an input to the scan channel is to be serially shifted through the plurality of memory elements of the scan channel; and circuitry to vary, based on a control signal, a number of the plurality of scan channels that have inputs coupled to a scan input signal, wherein for a first value of the control signal, all of the plurality of scan channels have inputs coupled to the scan input signal; for a second value of the control signal, only one of the plurality of scan channels has an input coupled to the scan input signal; and for a third value of the control signal, at least two but less than all of the plurality of scan channels have inputs coupled to the scan input signal.

Another aspect provides a method comprising accessing a scan chain comprising a plurality of scan channels coupled to combinational logic, wherein a scan channel comprises a plurality of memory elements arranged in series, wherein an input to the scan channel is to be serially shifted through the plurality of memory elements; selectively coupling, based on a value of a control signal, inputs of a first subset of the plurality of scan channels to a scan input signal, the scan input signal to communicate a test pattern; and selectively coupling, based on the value of the control signal, inputs of a second subset of the plurality of scan channels to outputs of other scan channels.

### BRIEF DESCRIPTION OF THE DRAWINGS

FIG. 1 illustrates a scan test architecture with a variable compression ratio, in accordance with any of the examples disclosed herein.

FIG. 2 illustrates compression configuration circuitry and observation configuration circuitry of the scan test architecture of FIG. 1, in accordance with any of the examples disclosed herein.

FIG. 3 illustrates a configuration table for the architecture of FIG. 2, in accordance with any of the examples disclosed herein.

FIG. 4 illustrates a method for utilizing scan test architecture with a variable compression ratio, in accordance with any of the examples disclosed herein.

FIG. 5 illustrates a scan test system for testing an integrated circuit, in accordance with any of the examples disclosed herein.

FIG. 6 illustrates an example computing system that may be used to implement features described herein, in accordance with any of the examples disclosed herein.

### DETAILED DESCRIPTION

Obtaining very high production test coverage is challenging for large digital devices in advanced silicon nodes. Scan-based testing is a near universal strategy and may utilize compression techniques wherein a common stimulus is broadcast into the inputs of multiple scan channels (where a scan channel may comprise a portion of a scan chain). The results may then be recombined at the scan channel outputs. However, commonly used compression schemes suffer from loss of coverage at very high compression ratios due to aliasing of input data across many scan channels and X-propagation forcing the masking of output data across many scan channels. The coverage loss can be mitigated by using a lower compression ratio, but at a cost of a longer scan chain requiring more production tester memory and longer production test time (where the compression ratio may be defined as the number of scan channels that may be connected to the same scan input signal relative to the total number of scan channels in a scan chain). The compression ratio is chosen during the design cycle and is a compromise between coverage and efficiency. Once the compression ratio is chosen, it is very difficult and expensive to change, as it may involve significant redesign. If the test coverage target cannot be met by the selected compression ratio, then very inefficient uncompressed top-up patterns are used. In an uncompressed scan, a multiplexer may be positioned at the head of each scan channel such that instead of broadcasting from a single pin (e.g., carrying a scan signal communicating a test pattern) into many scan channels, the input of each scan channel can alternately be connected to the output of the neighboring scan channel, resulting in one very long scan chain rather than many parallel shorter scan channels. Similar control logic may be implemented to simultaneously bypass an XOR tree on the output side. In this case there are no observation limitations, but the scan chain length increases enormously, resulting in very long test patterns.

As an example, various scan compression implementations may support a single fixed compression ratio for broadcast along with a fully uncompressed mode for “top-up” coverage. In such an implementation, a single scan input pin is broadcast to many shortened scan channels in parallel. An XOR operation is performed on the outputs of the scan channels and the results are provided to a single scan output pin. This may be done across multiple scan-in/scan-out pins in parallel, such that each input broadcasts to many scan channels and each output receives the XOR from many scan channels. However, the more scan channels a single pin broadcasts into, the less independent control is available for scan flip-flops in adjacent scan channels. Thus, it may not be possible to set all scan flip-flops into the intended target state to sensitize certain defects due to the aliasing of scan data across parallel scan channels. Likewise, if there are indeterminate states (known as X values) captured on individual flip-flops, the XOR tree may be corrupted, forcing the masking of many capture flip-flops across parallel scan channels. This loss of independent controllability and observability can result in either a loss of coverage, an increase in test pattern count, or both.

Various examples of the present disclosure provide independent per-scan channel mux control along with corresponding per-scan channel XOR bypass logic. This allows each scan channel to be loaded selectively either by broadcast or by serializing with its neighboring scan channel. Through the addition of a few extra gates, the scan compression ratio may be dynamically varied by serializing any arbitrary number of scan channels. As a result, an extremely high compression ratio may be chosen during design (e.g., beyond what would be reasonable under other schemes with less flexibility due to extreme coverage loss). Once the coverage at the highest compression ratio has been saturated, rather than switching to a fully uncompressed mode, a slightly reduced compression ratio may be selected and additional test patterns are generated and tested. Because the device is still in a compressed mode (albeit reduced from the maximum compression), these patterns may be significantly shorter than fully uncompressed patterns. This iterative approach may be repeated with additional successively reduced compression ratios until coverage targets have been satisfied (in at least some instances without ever requiring a fully uncompressed pattern to be generated).

Accordingly, in various examples of the present disclosure, the compression ratio of the scan chain may be adjusted (e.g., within the integrated circuit being tested) by selectively changing from broadcast to serialization on a scan channel by scan channel basis. Through addition of a per-scan channel serialize/broadcast control signal, a very high maximum compression ratio does not result in a compromise in test coverage since lower compression ratios can also be used as desired to increase test coverage while reducing test pattern volume and test time. Various examples described herein are also compatible with existing automatic test pattern generation (ATPG) tools, further improving the usability of such architectures.

In addition to allowing configurable compression, various examples may allow for selective suppression of individual scan channels’ contributions to an XOR tree communicating scan results. Thus, it may also be possible to use the scan architecture to mask particular scan channels for X-suppression which may improve coverage for certain difficult to detect defects at very high compression ratios. Additionally, by selectively suppressing the outputs of individual scan channels, various examples may significantly improve debug and diagnostics for broken scan chains, which are notoriously difficult to resolve.

Various examples described herein may provide one or more technical advantages, such as retaining production test cost efficiency of a very high compression ratio scan chain without loss of test coverage, reduction in manufacturing cost (e.g., reduced test equipment requirements, reduced test time), improved diagnostic capability for hard-to-localize defects (e.g., broken scan chains), or compatibility with existing ATPG tools.

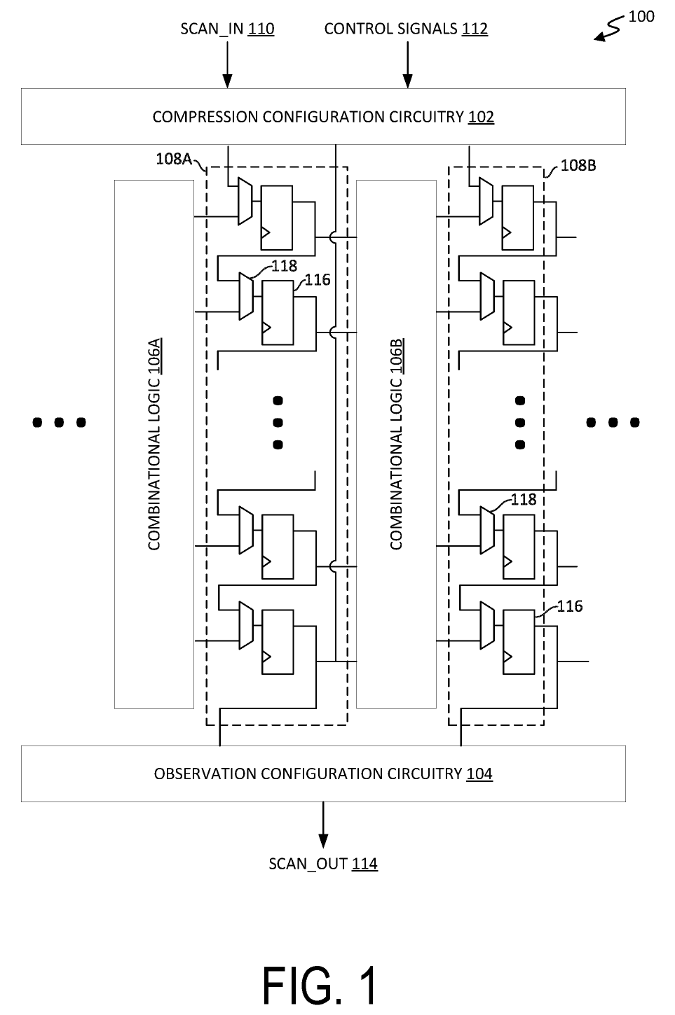

FIG. 1 illustrates a scan test architecture 100 with a variable compression ratio, in accordance with any of the examples disclosed herein. The scan test architecture 100 includes compression configuration circuitry 102, observation configuration circuitry 104, combinational logic blocks 106 (e.g., 106A, 106B), and scan channels 108 (e.g., 108A, 108B). The scan test architecture 100 receives a SCAN_IN signal 110 and control signals 112 as inputs, while outputting a SCAN_OUT signal 114.

The scan test architecture 100 may include any number of combinational logic blocks 106 and scan channels 108. A scan channel 108 includes a plurality of memory elements 116 (e.g., flip flops, registers, or other suitable memory element comprising circuitry to store and output a value) that are operable to store a value provided by the SCAN_IN signal 110 (which may be shifted through any number of memory elements 116 of one or more scan channels depending on the configuration). A scan channel also includes multiplexers 118 for the memory elements 116 that allow selection between multiple inputs. For example, a memory element 116 may receive its input from an output the corresponding multiplexer 118. The multiplexer may have inputs including, e.g., a data input and a scan input. The data input may be received from a combinational logic block 106 or other source (e.g., a data pin). Depending on the location of the multiplexer 118 and corresponding memory element 116, the scan input to the multiplexer 118 may be received from the SCAN_IN signal 110 or from an output of another memory element 116 of the scan chain.

The combinational logic blocks 106 include logic to be tested by the scan testing architecture. For example, a combinational logic block 106 may include any one or more of logic gates (e.g., AND, OR, NOT, NAND, NOR, XOR, XNOR gates), multiplexers, arithmetic logic units, decoders, encoders, comparators, state machines, or other suitable logic.

The combinational logic blocks 106 may be coupled to the scan channels and are collectively operational to receive input data from the outputs of the memory elements 116, perform logical operations, and provide output data to inputs of memory elements 116 (e.g., so that the output data may be scanned out). The combinational logic blocks may be coupled to the memory elements 116 or to each other using any suitable arrangements. For example, a combinational logic block 106 may be coupled to one or more of the scan channels (e.g., receiving inputs from or providing outputs to any number of the scan channels). Likewise, a combinational logic block 106 may be coupled to one or more other combinational logic blocks 106.

The control signals 112 may include any suitable signals to configure the compression configuration circuitry 102 or to facilitate the scanning of data through the scan channels 108. In some examples, the control signals 112 may include a scan clock that is provided to the memory elements 116 to time the operations of the memory elements 116. In various examples, the control signals 112 may include signals to configure the connectivity between the SCAN_IN signal 110 and the scan channels 108 as well as connectivity between adjacent scan channels. Thus, the control signals 112 may selectively configure the compression ratio (e.g., the number of scan channels to which the signal 110 is broadcast) of the scan test architecture 100, e.g., by selecting which scan channels receive their input from the SCAN_IN signal 110 and which scan channels receive their input from the last memory element 116 of the preceding scan channel.

In some instances, one or more of the control signals 112 may be used to control which scan channels output data that is used as the basis for the SCAN_OUT signal 114. Thus, one or more of the control signals 112 may additionally or alternatively be provided to the observation configuration circuitry 104 to configure the output of the scan chain.

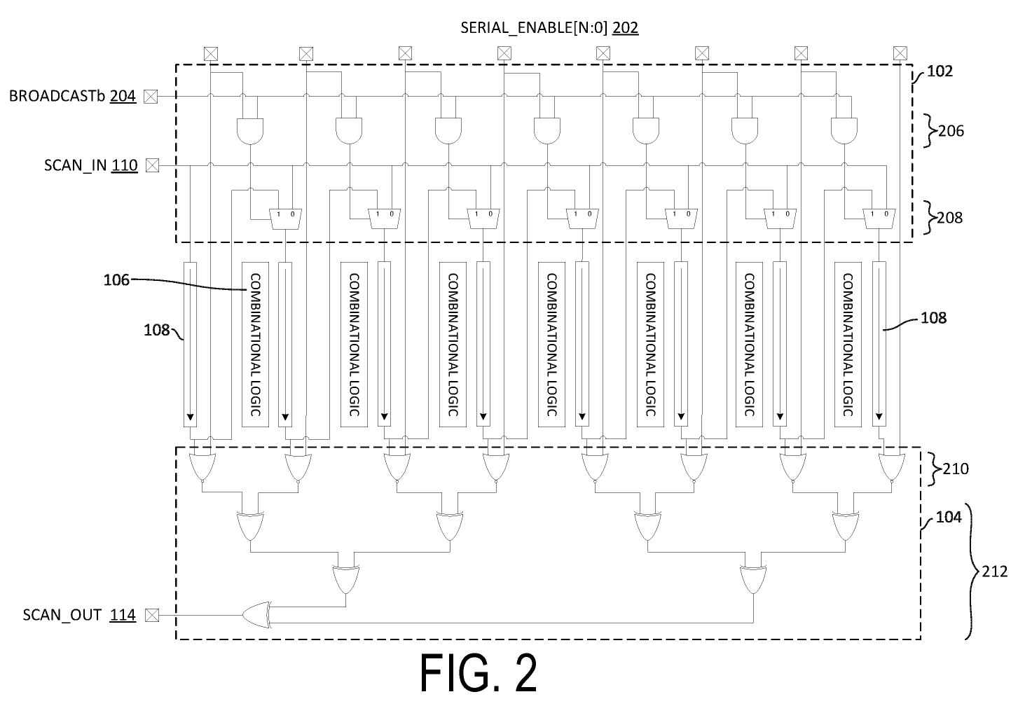

FIG. 2 illustrates compression configuration circuitry 102 and observation configuration circuitry 104 of the scan test architecture 100, in accordance with any of the examples disclosed herein.

In this example, control signals 112 include SERIAL_ENABLE signal 202 and BROADCASTb signal 204. In the example depicted, the number of bits of SERIAL_ENABLE signal 202 is equal to the number of scan channels 108. In this example, the SERIAL_ENABLE signal 202 is used to configure both the compression configuration circuitry 102 and the observation configuration circuitry 104. In other examples, first control signals may be used to control the compression configuration circuitry 102 and second control signals may be used to control the observation configuration circuitry 104.

Compression configuration circuitry 102 includes a plurality of AND gates 206 that receive the SERIAL_ENABLE signal 202 and the BROADCASTb signal 204 as inputs. A respective AND gate 206 receives the BROADCASTb signal and one bit of the SERIAL_ENABLE signal 202. The output of an AND gate 206 is provided as a selector input to a corresponding multiplexer 208. A multiplexer 208 receives the SCAN_IN signal 110 at one input and an output of a last memory element 116 of a scan channel 108 at the other input. The selector input controls which of the inputs is provided to the first memory element 116 of the next scan channel 108. In the example depicted, an AND gate 206 and multiplexer 208 is provided for all of the scan channels 108 except for the first scan channel 108 (which always receives its input from the SCAN_IN signal 110). In this example, all of the bits of the SERIAL_ENABLE signal 202 are provided to respective AND gates 206 except for the last signal which is not used to control the compression configuration circuitry 102 but rather is provided to the observation configuration circuitry 104.

Observation configuration circuitry 104 includes NOR gates 210 and XOR tree 212. A respective NOR gate 210 receives a SERIAL_ENABLE signal 202 as a first input and an output of a last memory element 116 of a scan channel 108 as a second output. The output of a NOR gate 210 is provided to the XOR tree 212. The output of the XOR tree 212 is provided as the SCAN_OUT signal 114.

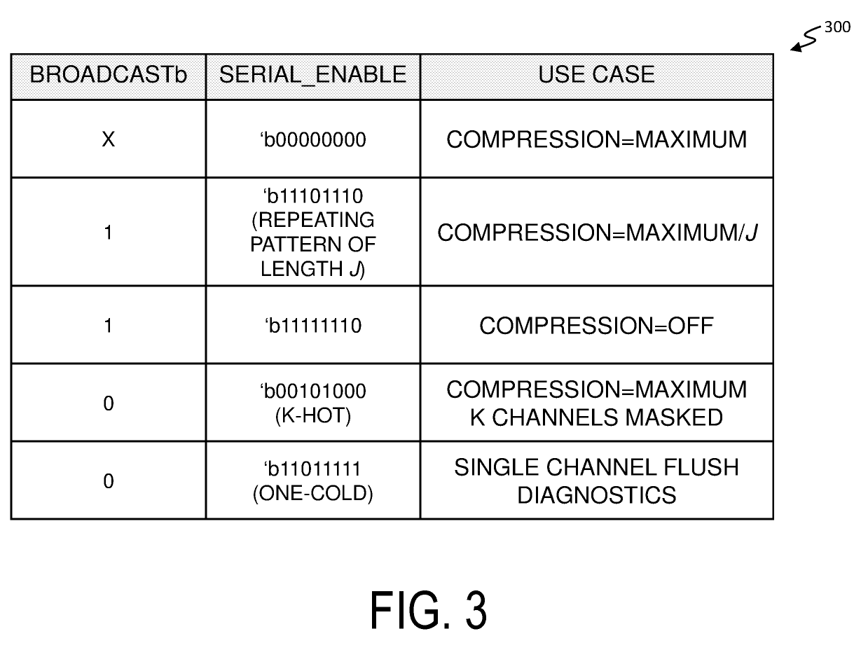

Example modes of operation for scan test architecture 100 will now be described with respect to FIGS. 2 and 3. As depicted in the first row of table 300 of FIG. 3, all of the bits of the SERIAL_ENABLE signal 202 are set to 0. In this instance, the value of the BROADCASTb signal 204 is irrelevant (and thus is represented as X in the table). This set of values for the control signals 112 sets the scan test architecture 100 to a maximum compression mode. In this mode the AND gates 206 of the 102 will propagate 0 values to the multiplexers 208 and the multiplexers will all be set to broadcast mode such that all scan channels 108 will take input directly from the SCAN_IN signal 110. Thus, in this mode, the SCAN_IN signal 110 will broadcast into all scan channels 108 simultaneously. In this mode, the bits of the SERIAL_ENABLE signal 202 propagate down to the NOR gates 210 at the output such that all scan channel outputs will propagate into the XOR tree 212 (thus SCAN_OUT signal 114 is an XOR of the outputs of all of the individual scan channels 108).

As depicted in the second row of table 300, the BROADCASTb signal 204 is set to 1, and the collective value of the bits of the SERIAL_ENABLE signal 202 is set to a repeating pattern of one or more consecutive 1s (the number of 1s is depicted as J-1) and a single 0. In the example depicted in table 300, J is equal to 4 so the number of consecutive 1s is 3. In this mode, the compression of the scan test architecture 100 (e.g., the number of scan channels 108 that receive their input from the SCAN_IN signal 110) is equal to the maximum compression value (e.g., the number of scan channels 108) divided by J. Thus, the compression is equal to 2 in this instance.

The objective in this mode is to use the per-channel control bits (e.g., SERIAL_ENABLE signal 202) to select on a channel-by-channel basis whether the scan channel is receiving its input from the SCAN_IN signal 110 or from its preceding neighbor scan channel (e.g., the scan channel to its left in the illustration). The bits of the SERIAL_ENABLE signal 202 also control whether the corresponding scan channels contribute to the XOR tree 212 (e.g., whether the captured values are propagated into the output at the end of that scan channel).

For the scan channels where the corresponding SERIAL_ENABLE signal is set to 1, the input data for that scan channel 108 is the output from the preceding neighbor scan channel (thus this scan channel will be serialized with this neighbor scan channel instead of receiving its input from the SCAN_IN signal 110) and the preceding neighbor scan channel will be suppressed from contributing to the XOR tree 212. For example, if the leftmost bit of SERIAL_ENABLE signal 202 is set to 1, the two scan channels on the left will effectively be combined into a single scan channel with a greater length and with no contribution to the XOR tree 212 from the left most channel. Rather, the output of the second scan channel (which is the output of the combined scan channel) is provided to the XOR tree 212. Thus, an individual scan channel may be configured to bypass its contribution into the XOR tree 212 and instead be serialized into the next scan channel.

Although any values of bits may be set for SERIAL_ENABLE signal 202, certain values may facilitate efficient scan testing. For example, a compression scheme may follow an approach where the compression ratio reduces by half for successive test pattern sets. For example, for the first set of test patterns, the compression ratio may be set to a maximum, e.g., by setting the SERIAL_ENABLE signal 202 to 00000000…(where the ellipses represents the indicated pattern repeating any number of times depending on the number of scan channels and corresponding bits of SERIAL_ENABLE signal 202). For the second set of test patterns, the compression ratio may be set to the maximum/2 (e.g., by setting the SERIAL_ENABLE signal 202 to 10101010…). For the third set of test patterns, the compression scheme may be set to the maximum/4 (e.g., by setting the SERIAL_ENABLE signal 202 to 11101110…). For the fourth set of test patterns, the compression scheme may be set to the maximum/8 (e.g., by setting the SERIAL_ENABLE signal 202 to 11111110…), and so on until the desired test coverage is reached.

Thus, the first set of test patterns from the SCAN_IN signal 110 would be broadcast into all scan channels, the second set of test patterns would be broadcast into every other scan channel, the third set of test patterns would be broadcast into every fourth scan channel, the fourth set of test patterns would be broadcast into every eighth scan channel, and so on.

As depicted in the third row of table 300, the BROADCASTb signal 204 is set to 1, and the bits of SERIAL_ENABLE signal 202 are all set to 1s except for the last bit which is set to 0. In this case, each scan channel (other than the first scan channel) will receive as its input the output of the preceding scan channel (e.g., the scan channel to its left). Every scan channel except the last scan channel will also be masked off from the output (e.g., the XOR tree 212). As the bit for the last scan channel is set to 0, the output of the last scan channel is provided to the output (if it were set to 1, the last NOR gate would result in all contributions to the output being blocked). Thus, this mode is a fully uncompressed scheme where the SCAN_IN signal 110 passes through every memory element 116 in the scan chain (composed of each of the chained scan channels 108).

As depicted in the fourth row of table 300, the BROADCASTb signal 204 is set to 0, and a k-hot scheme is used for the bits of SERIAL_ENABLE signal 202. Setting the BROADCASTb signal 204 to 0 enables diagnostic capabilities. The deassertion of the BROADCASTb signal 204 forces inputs into the scan channels 108 to come from the SCAN_IN signal 110 (and thus compression is set to its maximum). From a controllability perspective, individual bits of the SERIAL_ENABLE signal 202 may still be used to selectively disable contributions to the XOR tree 212. Accordingly, if one scan channel is the source of unknown results (which may severely limit coverage since results from that scan channel may corrupt results of other scan channels), the appropriate bit of the SERIAL_ENABLE signal 202 may be used to prevent the output of that scan channel from propagating into the XOR tree. Thus, when in the k-hot scheme mode, the bits that are set to 1 may disable the corresponding scan channels from contributing their outputs to the XOR tree 212.

As depicted in the fifth row of table 300, the BROADCASTb signal 204 is set to 0, and a single bit of the SERIAL_ENABLE signal 202 is set to 0. In this instance, only a single scan channel is allowed to provide its output to the XOR tree 212. Such an implementation may be valuable for diagnostics purposes as it may provide for observation of broken scan chains and may allow determination of which scan channel has the error.

In various examples, at least some of the control signals 112 (e.g., SERIAL_ENABLE signal 202 and the BROADCASTb signal 204) are set from on-chip registers that are written to by a test interface coupled to the chip (e.g., via a Joint Test Action Group (JTAG) interface). These registers may be top level control bits or per-block internal registers depending on the hierarchical implementation. Alternatively, these signals may be supplied from a source off of the chip (e.g., via a pin of the chip). The SCAN_IN signal 110 and SCAN_OUT out signal 114 may be coupled to respective pins on the chip. Alternatively, the SCAN_IN signal 110 may be coupled to a pattern generator of the chip (e.g., a linear feedback shift register (LFSR) or other pseudorandom pattern generator).

Although a single scan chain is illustrated along with an associated SCAN_IN signal 110 and SCAN_OUT signal 114 and control signals 112, in other examples a chip may include any suitable number of scan chains with respective scan and control signals that may be operated in parallel. In some examples, two or more scan chains may share any of these signals (or independent signals may be provided for each scan chain). Although the example depicted includes eight scan channels for the scan chain, a scan chain may include any suitable number of scan channels.

In some examples, the control of the compression configuration circuitry 102 may be separate from the control of the observation configuration circuitry 104 (e.g., different signals may control the different blocks).

In various examples, compression configuration circuitry 102 may be arranged differently, while still providing control of which scan channels 108 receive their input from the SCAN_IN signal 110 and which receive their input from the preceding neighbor scan channel. For example, the AND gates 206 and the BROADCASTb signal 204 may be omitted and the SERIAL_ENABLE signal 202 may be provided directly to the selection inputs of the multiplexers 208, thus preserving control of the multiplexers 208 and gating off the outputs (thus maintaining enablement of variable compression). In yet other examples, additional wiring may enable more variability in the chaining together of scan channels 108. For example, an output of a particular scan channel 108 could be provided as input to any other scan channel 108 (which could be selected using, e.g., a multiplexer). As another example, an output of a particular scan channel 108 may be provided as input for a subset of the scan channels (e.g., the neighboring scan channel or the neighbor of the neighbor).

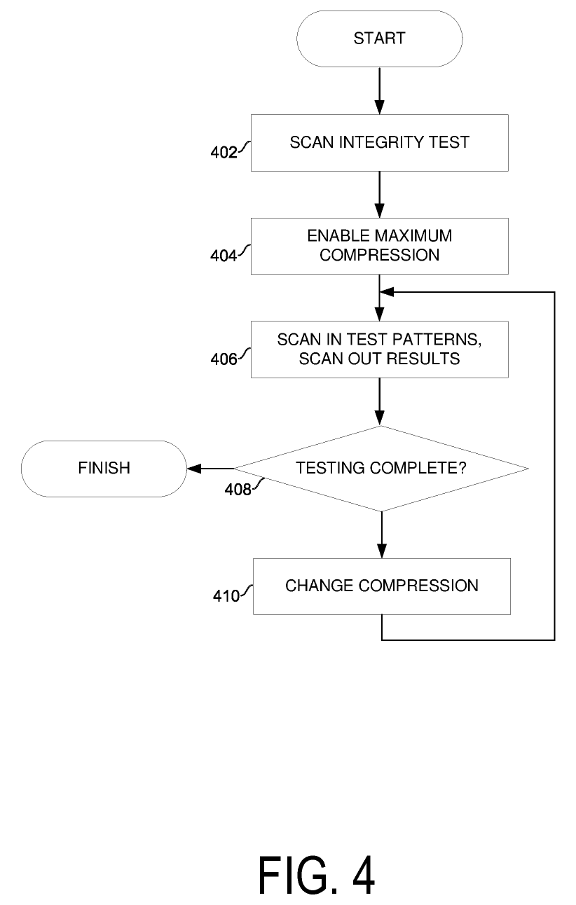

FIG. 4 illustrates a method for utilizing a scan test architecture with a variable compression ratio, in accordance with any of the examples disclosed herein. The various operations may be performed by any suitable logic, such as scan test system 500 (described below) in conjunction with a scan test architecture 100, integrated circuit 510, or other device under test.

At 402, a scan integrity test may be performed to verify that the scan channels themselves are working properly 108 (e.g., without loading data from the combination logic blocks 106 into the memory elements 116). This may involve, for example, shifting data into the scan chain, shifting the data out, and verifying that the output matches the input.

At 404, maximum compression is enabled, such that the scan test patterns are broadcast to each scan channel. At 406, test patterns are scanned into the scan channels and provided to the combinational logic. Results from the combinational logic are then captured by the memory elements 116 and then scanned out via the scan channels. The results may be compared against expected results (e.g., as derived from a logical representation of the chip and based on the scan test patterns) to determine whether any defects exist.

At 408, a determination of whether testing is complete is made. If testing is not complete, the flow moves to 410 where the compression scheme for the scan test architecture 100 is changed (e.g., by chaining certain scan channels together). For example, the compression ratio may be reduced (e.g., by half). The flow then returns to 406. The operations of the flow may be repeated until testing is complete and the flow finishes.

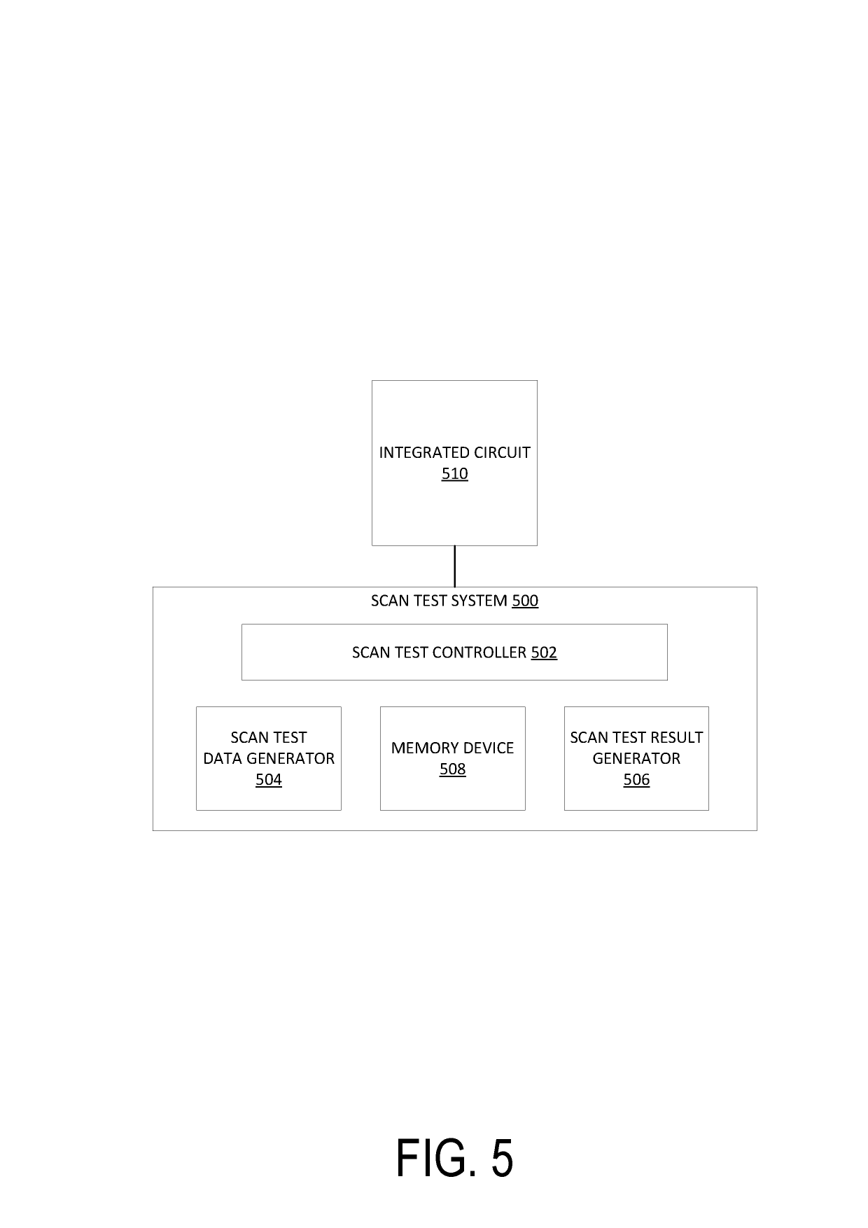

FIG. 5 illustrates a scan test system 500 for testing an integrated circuit 510, in accordance with any of the examples disclosed herein. The scan test system 500 may include a scan test controller 502, a scan test data generator 504, a scan test result generator 506, and a memory device 508. The various components of scan test system 500 may include any suitable logic.

The integrated circuit 510 includes one or more combinational logic circuits and scan chain circuits including memory elements connected to the combinatorial logic circuits and forming one or more scan paths. In various examples, the integrated circuit 510 may include any of the architectures described herein, such as scan test architecture 100, any subset of components of scan test architecture 100, or variations thereof.

The scan test controller 502 may control a scan test for the integrated circuit 510 by interacting with the integrated circuit 510, memory device 508, scan test data generator 504, and scan test result generator 506. In various examples, the scan test system 500 may generate a test pattern, shift the test pattern into a scan chain circuit of the integrated circuit 510, capture (into the scan chain circuit) a result value produced by the one or more combinational logic circuits of the integrated circuit 510 based on the test pattern, and shift out the result value from the scan chain circuit.

Memory device 508 may store data that is used by the scan test system 500 to perform a scan test. As examples, the memory device 508 may store one or more of a test pattern that is generated by the scan test data generator 504 and shifted into a scan chain circuit, a result value generated by one or more combinational logic circuits based on the test pattern, a reference pattern for comparison with the result value, or a test result output by the scan test result generator 506. Memory device 508 may include any form of volatile memory or non-volatile memory including, without limitation, random access memory (RAM), dynamic random access memory (DRAM), static random access memory (SRAM), ferroelectric random access memory (FeRAM), read-only memory (ROM), erasable programmable read-only memory (EPROM), electrically erasable read-only memory (EEPROM), flash memory, removable media, optical media, magnetic media (e.g., tape drives), any other suitable memory components, or any suitable combination thereof.

The scan test result generator 506 may generate test results by comparing the result value with a reference pattern. As an example, if the result value matches the reference pattern, the scan test result generator 506 may provide a test result that indicates that the combinational logic circuit is free of defects, but when the result value does not match the reference pattern, the scan test result generator 506 may output a test result indicating that the combinational logic circuit includes at least one defect.

In some instances, the scan test system 500 may generate any of the signals used to control the scan testing described herein (or signals that trigger an integrated circuit to generate such signals), such as SCAN_IN signal 110 (which may in some instances be generated by the scan test data generator 504), control signals 112, SERIAL_ENABLE signal 202, or BROADCASTb signal 204. The scan test system 500 may also receive the SCAN_OUT signal 114 and compare it to the reference pattern.

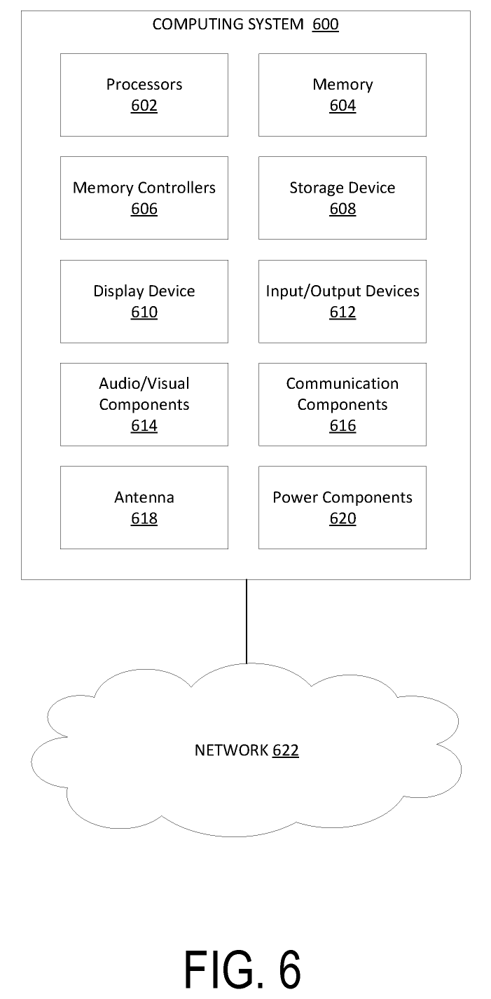

FIG. 6 illustrates an example computing system 600 that may be used to implement features described herein, in accordance with any of the examples disclosed herein. For example, computing system 600 illustrates a computer architecture that may be used to implement any of the systems described herein (e.g., scan test architecture 100, scan test system 500, integrated circuit 510) or any suitable combination thereof. In some instances, any one or more of the components of computing system 600 illustrated herein may be included within an integrated circuit with a scan chain and combinational logic to be tested according to various examples described herein.

Computing system 600 includes one or more processors 602, memory 604, memory controllers 606, storage device 608, display device 610, input/output devices 612, audio/visual components 614, communication components 616, antenna 618, and power components 620.

One or more of processors 602 may include processing devices or processing units that include suitable hardware circuitry to enable the execution of instructions and the ability to perform calculations to carry out the operations of software, firmware, hardware, or any suitable combination thereof. Any suitable operations disclosed herein may be performed by one or more of the processors 602. One or more of the processors 602 may be embodied as single-core processing devices or multi-core processing devices.

Nonlimiting examples of possible types of processing devices include a central processing unit (CPU), a microprocessor, an embedded processor, a digital signal processor (DSP), a system-on-a-chip (SoC), a co-processor, microcontroller, an accelerator, a graphics processing unit (GPU), an accelerated processing unit (APU), a visual processing unit (VPU), a deep learning processor (DLP), a neural network processing unit (NPU), a general purpose graphics processing unit (GPGPU), an inference accelerator, an application-specific integrated circuit (ASIC), a field-programmable gate array (FPGA), or any other processing device to execute code. One or more of the processors 602 may perform specialized processing tasks (e.g., graphics processing by GPUs, machine learning by DLPs, vision processing by VLPs, or the like). In some examples, one or more of the processors 602 may perform specialized processing tasks on behalf of one or more other processing devices such as CPUs or GPUs.

Memory 604 includes one or more memory devices that store data to be manipulated, generated, or otherwise used by processors 602 when performing operations. Memory 604 may include any form of volatile memory or non-volatile memory including, without limitation, random access memory (RAM), dynamic random access memory (DRAM), static random access memory (SRAM), ferroelectric random access memory (FeRAM), read-only memory (ROM), erasable programmable read-only memory (EPROM), electrically erasable read-only memory (EEPROM), flash memory, removable media, optical media, magnetic media (e.g., tape drives), any other suitable memory components, or any suitable combination thereof. Memory 604 may include one or more memory devices within the computing system, one or more memory devices separate from but communicatively coupled to the computing system, or a suitable combination thereof.

A memory hierarchy in computing system 600 may include one or more levels of cache (e.g., level one (L1), level two (L2), level three (L3), other levels of cache or combinations thereof). The cache levels may be within, close to, or accessible by the one or more processors 602. For example, some cache may be close to or within a core of one processor and accessible by only that core. Another cache level may be close to a core of a processor and shared with (and therefore, accessible by) another core of the same processor or a different processor.

Memory devices of memory 604 may include one or more modules or layers of system memory coupled to the processors 602 through one or more memory controllers 606. Generally, the system memory may be some form of volatile memory (e.g., DRAM, RAM, SRAM, etc.). A portion or more of the system memory may be dedicated to a particular processing device. A portion or more of the system memory may be shared across one or more of the processors 602 in the computing system.

Memory controllers 606 are hardware interfaces including hardware components that are integrated with, or external to, the processors 602. Memory controllers 606 can manage communication between processors 602 (e.g., a CPU, a GPU) and memory (e.g., DRAM). In addition to memory controllers 606, other memory controller circuitry that may be included in computing system 600 may include, but is not necessarily limited to memory management units (MMUs), translation lookaside buffers (TLBs), load and store buffers, an address generation unit (AGU), an address decoder, and more. The memory controller circuitry may include electrical components, optical components, quantum components, semiconductor devices, logic elements, or any suitable combination thereof, to perform operations to read/load from memory and write/store to memory. Data may be read/loaded from the closest memory where it is stored (e.g., cache memory, system memory, storage devices, or remote memory). In addition, data may be written/stored to cache before being written/stored in system memory or a storage device.

Storage device 608 generally includes non-volatile memory and may include any suitable characteristics described above with respect to memory 604. In many instances, storage device 608 may have higher capacity and slower speed than memory 604. Thus, storage device 608 may be typically (although not always exclusively) used for longer term storage. In some examples, storage device 608 includes one or more non-volatile storage devices such as hard disk drives (HDDs), solid state drives (SSDs), removable storage devices (e.g., flash drives), other media (e.g., transitory machine readable media, non-transitory machine readable media), or any suitable combination thereof.

Display device 610 and input/output devices 612 may be interfaces that enable a human user to interact with the computing system 600. The display device 610 may include any suitable screen or monitor that visually presents data in the form of text, images, video, graphical information, other data or information, or any combination thereof. The display device 610 may be integrated within the computing system (e.g., as a laptop screen, tablet screen, smart phone screen, etc.) or may be an external device (e.g., a desktop monitor, external monitor, etc.) that is communicatively connected to the computing system 600. Data may be generated by the one or more processors 602 or received as input (e.g., from a human user via an input device) and provided for display on the display device 610. In some scenarios, one or more additional display devices may be integrated within, or communicatively connected to, the computing system 600. Input/output devices 612 may be interfaces to enable communications from and to a human user. Input/output devices 612 may include, without limitation, a keyboard, a mouse, touchscreen on a display device (e.g., display device 610), trackball, or the like.

Audio/visual components 614 may include devices to provide audio or visual signals and may include, e.g., a web camera, a microphone, a speaker, or the like. Audio/visual devices may be integrated or built into the computing system 600 or separate from and communicatively coupled to the computing system 600.

Communication components 616 may include hardware software, firmware, or suitable combination thereof to facilitate communications via a network 622 coupled to the computing system 600. For example, communication components 616 may include one or more network interface controllers, network drivers and firmware, modem, router, switch, adapters, or other suitable components.

The network 622 can include any type or topology of networks and represents a series of points or nodes of interconnected communication pathways for receiving and sending network communications. Network 622 offers a communicative interface between nodes (e.g., computing system 600 and one or more remote devices also coupled to the network) and may be configured as any local area network (LAN), virtual local area network (VLAN), wide area network (WAN), Internet, Intranet, Extranet, virtual private network (VPN), cloud network, any other appropriate architecture or system that facilitates communications in a network environment, or any suitable combination thereof. Network 622 can use any suitable technologies for communication including wireless (e.g., 3G/4G/5G/nG network, Wireless Fidelity (Wi-Fi), worldwide interoperability for microwave access (WiMax), radio-frequency identification (RFID), near field communication (NFC), Bluetooth, or the like), wired (e.g., ethernet, fiber optic cables, powerlines, T1 lines, etc.), or a suitable combination thereof.

An antenna 618 may be provided in the computing system 600 to facilitate at least some wireless communications. For example, antenna 618 may be provided to enable sending and receiving wireless communications, including receiving AM or FM radio transmissions.

Power components 620 manage the conversion, distribution, and regulation of electrical power for various subsystems of the computing system 600. Power components 620 may include, for example, one or more power supply units to convert AC power to DC power, voltage regulators to step down voltage from the power supply unit, power management integrated circuits (PMICs) to control power sequencing and delivery, batteries (e.g., to provide the main source of power to computing system 600 or to provide an auxiliary power source, e.g., to retain BIOS or UEFI settings).

As used herein, the term “logic” may refer to hardware (e.g., circuitry), firmware, software, or any combination thereof configured to perform one or more functions. Logic may be implemented using digital circuits such as combinational logic gates, sequential circuits, programmable logic devices, application-specific integrated circuits (ASICs), field-programmable gate arrays (FPGAs), microprocessors, or microcontrollers. In some embodiments, logic may also include software or firmware instructions stored in memory and executed by one or more processing units.

As used herein, the term “or” is intended to be inclusive rather than exclusive. That is, unless otherwise indicated or as would be apparent to one of skill in the art, the use of “or” should be interpreted to mean “and/or.” For example, the phrase “A or B” should be understood to mean “A, B, or both A and B.” The singular terms "a," "an," and "the" are intended to encompass their plural counterparts as well, unless it is clear from the context that a different interpretation is intended. Herein, when a list of items is preceded by phrases such as “at least one of” or “one or more of,” it is intended to allow for any combination of the listed elements.

In the drawings, while some structural or method features may be shown in specific arrangements or orderings, such specific arrangements or orderings may be optional. In some examples, such features may be arranged in a different manner or order than shown in the drawings. Additionally, the inclusion of a structural or method feature in a particular drawing is not meant to imply that such feature is present in all examples, and, in some examples, such feature may not be included or may be combined with other features. Further, the various examples shown in the drawings are illustrative representations and may not be drawn to scale. In some instances, the same or similar reference numerals may be used to designate the same or similar features in different drawings.

The following examples pertain to the subject matter disclosed herein. In accordance with this specification, a system, apparatus, method, machine readable storage media, or a combination thereof, can include features from one or a combination of the following examples.

Example 1 includes a system comprising a scan chain comprising a plurality of scan channels coupled to combinational logic, wherein a scan channel comprises a plurality of memory elements arranged in series, wherein an input to the scan channel is to be serially shifted through the plurality of memory elements of the scan channel; and circuitry to, based on a value of a control signal couple inputs of a first subset of the plurality of scan channels to a scan input signal, the scan input signal to communicate a test pattern; and couple inputs of a second subset of the plurality of scan channels to outputs of other scan channels of the plurality of scan channels.

Example 2 includes the subject matter of Example 1, and wherein the control signal comprises a plurality of bits that correspond to the plurality of scan channels, wherein a first bit corresponding to a first scan channel specifies whether an output of the first scan channel is to be coupled to an input of a second scan channel.

Example 3 includes the subject matter of any of Examples 1 and 2, and wherein the first bit further specifies whether an output of the first scan channel is to be provided to an output circuit of the scan chain.

Example 4 includes the subject matter of any of Examples 1-3, and wherein the output circuit of the scan chain comprises an XOR tree.

Example 5 includes the subject matter of any of Examples 1-4, and wherein the control signal comprises a plurality of bits that correspond to the plurality of scan channels, wherein a first bit corresponding to a first scan channel specifies whether an output of the first scan channel is to be provided to an output circuit of the scan chain.

Example 6 includes the subject matter of any of Examples 1-5, and wherein the circuitry is to, responsive to a change in the value of the control signal, change a compression ratio of the scan chain by changing a number of scan channels with inputs that are coupled to the scan input signal and a number of scan channels with inputs that are coupled to other scan channels.

Example 7 includes the subject matter of any of Examples 1-6, and wherein the circuitry is to, based on a second value of the control signal, couple inputs of the first subset and the second subset of the plurality of scan channels to the scan input signal.

Example 8 includes the subject matter of any of Examples 1-7, and wherein the circuitry is to, based on a third value of the control signal, reconfigure connectivity of the plurality of scan channels so that an input of a first scan channel is coupled to the scan input signal and inputs of the scan channels other than the first scan channel are coupled to outputs of other scan channels.

Example 9 includes the subject matter of any of Examples 1-8, and further including an integrated circuit die comprising the scan chain and circuitry.

Example 10 includes the subject matter of any of Examples 1-9, and further including one or more of a network interface, a graphics processor, or an input/output controller coupled to the integrated circuit die.

Example 11 includes an apparatus comprising a scan chain comprising a plurality of scan channels coupled to combinational logic, wherein a scan channel comprises a plurality of memory elements arranged in series, wherein an input to the scan channel is to be serially shifted through the plurality of memory elements of the scan channel; and circuitry to vary, based on a control signal, a number of the plurality of scan channels that have inputs coupled to a scan input signal, wherein for a first value of the control signal, all of the plurality of scan channels have inputs coupled to the scan input signal; for a second value of the control signal, only one of the plurality of scan channels has an input coupled to the scan input signal; and for a third value of the control signal, at least two but less than all of the plurality of scan channels have inputs coupled to the scan input signal.

Example 12 includes the subject matter of Example 11, and wherein for the second value and the third value of the control signal, the circuitry is to couple inputs of the scan channels that do not have inputs coupled to the scan input signal to outputs of neighboring scan channels.

Example 13 includes the subject matter of any of Examples 11 and 12, and wherein for the third value of the control signal, the circuitry is further to mask off outputs of the at least two but less than all of the plurality of scan channels from an output circuit of the scan chain.

Example 14 includes the subject matter of any of Examples 11-13, and wherein the control signal comprises a plurality of bits that correspond to the plurality of scan channels, wherein a first bit corresponding to a first scan channel specifies whether an output of the first scan channel is to be coupled to an input of a second scan channel.

Example 15 includes the subject matter of any of Examples 11-14, and wherein the circuitry comprises a plurality of multiplexers that selectively couple the inputs of the scan channels to the scan input signal or to outputs of other scan channels, wherein the multiplexers are controlled by the control signal and by a second control signal.

Example 16 includes a method comprising accessing a scan chain comprising a plurality of scan channels coupled to combinational logic, wherein a scan channel comprises a plurality of memory elements arranged in series, wherein an input to the scan channel is to be serially shifted through the plurality of memory elements; selectively coupling, based on a value of a control signal, inputs of a first subset of the plurality of scan channels to a scan input signal, the scan input signal to communicate a test pattern; and selectively coupling, based on the value of the control signal, inputs of a second subset of the plurality of scan channels to outputs of other scan channels.

Example 17 includes the subject matter of Example 16, and further including selectively coupling outputs of the plurality of scan channels to an output circuit of the scan chain based on the value of the control signal.

Example 18 includes the subject matter of any of Examples 16 and 17, and wherein the control signal comprises a plurality of bits that correspond to the plurality of scan channels, wherein a first bit corresponding to a first scan channel specifies whether an output of the first scan channel is to be coupled to an input of a second scan channel.

Example 19 includes the subject matter of any of Examples 16-18, and wherein the control signal comprises a plurality of bits that correspond to the plurality of scan channels, wherein a first bit corresponding to a first scan channel specifies whether an output of the first scan channel is to be provided to an output circuit of the scan chain.

Example 20 includes the subject matter of any of Examples 16-19, and further including changing a compression ratio of the scan chain by changing a number of scan channels with inputs that are coupled to the scan input signal and a number of scan channels with inputs that are coupled to other scan channels.

While the concepts of the present disclosure are susceptible to various modifications and alternative forms, specific examples thereof have been shown in the drawings and are described herein in detail. However, the concepts of the present disclosure are not limited to the particular forms disclosed, but on the contrary, all modifications, equivalents, and alternatives consistent with the present disclosure and the appended claims are also covered.

1. A system comprising:
a scan chain comprising a plurality of scan channels coupled to combinational logic, wherein a scan channel comprises a plurality of memory elements arranged in series, wherein an input to the scan channel is to be serially shifted through the plurality of memory elements of the scan channel; and
circuitry to, based on a value of a control signal:
couple inputs of a first subset of the plurality of scan channels to a scan input signal, the scan input signal to communicate a test pattern; and
couple inputs of a second subset of the plurality of scan channels to outputs of other scan channels of the plurality of scan channels.

2. The system of claim 1, wherein the control signal comprises a plurality of bits that correspond to the plurality of scan channels, wherein a first bit corresponding to a first scan channel specifies whether an output of the first scan channel is to be coupled to an input of a second scan channel.

3. The system of claim 2, wherein the first bit further specifies whether an output of the first scan channel is to be provided to an output circuit of the scan chain.

4. The system of claim 3, wherein the output circuit of the scan chain comprises an XOR tree.

5. The system of claim 1, wherein the control signal comprises a plurality of bits that correspond to the plurality of scan channels, wherein a first bit corresponding to a first scan channel specifies whether an output of the first scan channel is to be provided to an output circuit of the scan chain.

6. The system of claim 1, wherein the circuitry is to, responsive to a change in the value of the control signal, change a compression ratio of the scan chain by changing a number of scan channels with inputs that are coupled to the scan input signal and a number of scan channels with inputs that are coupled to other scan channels.

7. The system of claim 1, wherein the circuitry is to, based on a second value of the control signal, couple inputs of the first subset and the second subset of the plurality of scan channels to the scan input signal.

8. The system of claim 7, wherein the circuitry is to, based on a third value of the control signal, reconfigure connectivity of the plurality of scan channels so that an input of a first scan channel is coupled to the scan input signal and inputs of the scan channels other than the first scan channel are coupled to outputs of other scan channels.

9. The system of claim 1, further comprising an integrated circuit die comprising the scan chain and circuitry.

10. The system of claim 9, further comprising one or more of a network interface, a graphics processor, or an input/output controller coupled to the integrated circuit die.

11. An apparatus comprising:
a scan chain comprising a plurality of scan channels coupled to combinational logic, wherein a scan channel comprises a plurality of memory elements arranged in series, wherein an input to the scan channel is to be serially shifted through the plurality of memory elements of the scan channel; and
circuitry to vary, based on a control signal, a number of the plurality of scan channels that have inputs coupled to a scan input signal, wherein:
for a first value of the control signal, all of the plurality of scan channels have inputs coupled to the scan input signal;
for a second value of the control signal, only one of the plurality of scan channels has an input coupled to the scan input signal; and
for a third value of the control signal, at least two but less than all of the plurality of scan channels have inputs coupled to the scan input signal.

12. The apparatus of claim 11, wherein for the second value and the third value of the control signal, the circuitry is to couple inputs of the scan channels that do not have inputs coupled to the scan input signal to outputs of neighboring scan channels.

13. The apparatus of claim 11, wherein for the third value of the control signal, the circuitry is further to mask off outputs of the at least two but less than all of the plurality of scan channels from an output circuit of the scan chain.

14. The apparatus of claim 11, wherein the control signal comprises a plurality of bits that correspond to the plurality of scan channels, wherein a first bit corresponding to a first scan channel specifies whether an output of the first scan channel is to be coupled to an input of a second scan channel.

15. The apparatus of claim 11, wherein the circuitry comprises a plurality of multiplexers that selectively couple the inputs of the scan channels to the scan input signal or to outputs of other scan channels, wherein the multiplexers are controlled by the control signal and by a second control signal.

16. A method comprising:
accessing a scan chain comprising a plurality of scan channels coupled to combinational logic, wherein a scan channel comprises a plurality of memory elements arranged in series, wherein an input to the scan channel is to be serially shifted through the plurality of memory elements;
selectively coupling, based on a value of a control signal, inputs of a first subset of the plurality of scan channels to a scan input signal, the scan input signal to communicate a test pattern; and
selectively coupling, based on the value of the control signal, inputs of a second subset of the plurality of scan channels to outputs of other scan channels.

17. The method of claim 16, further comprising selectively coupling outputs of the plurality of scan channels to an output circuit of the scan chain based on the value of the control signal.

18. The method of claim 16, wherein the control signal comprises a plurality of bits that correspond to the plurality of scan channels, wherein a first bit corresponding to a first scan channel specifies whether an output of the first scan channel is to be coupled to an input of a second scan channel.

19. The method of claim 16, wherein the control signal comprises a plurality of bits that correspond to the plurality of scan channels, wherein a first bit corresponding to a first scan channel specifies whether an output of the first scan channel is to be provided to an output circuit of the scan chain.

20. The method of claim 16, further comprising changing a compression ratio of the scan chain by changing a number of scan channels with inputs that are coupled to the scan input signal and a number of scan channels with inputs that are coupled to other scan channels.
